(19) United States
(12) Patent Application Publication
(10) Pub. No.: US 2008/0079435 A1
(43) Pub. Date: Apr. 3, 2008

(54) Electrostatic Voltmeter With Spacing-Independent Speed of Response

(75) Inventors: Bruce T. Williams, Lockport, NY (US); Jerzy Kieres, East Amherst, NY (US)

Correspondence Address: HODGSON RUSS LLP;THE GUARANTY BUILDING, 140 PEARL STREET, SUITE 100, BUFFALO, NY, 14202-4040, US

(73) Assignee: TREK, INC., Medina, NY (US)

(21) Appl. No.: 11/530,238

(22) Filed: Sep. 8, 2006

(51) Int. Cl. G01R 29/12

(52) U.S. Cl. 324/457

(57) ABSTRACT

A non-contacting electrostatic voltmeter (ESVM) technique and apparatus having a spacing-independent dynamic response characteristic. Using the disclosed technique, an ESVM apparatus is capable of detecting and measuring electrostatic voltages and/or fields over wide variations of sensing probe to measured surface spacing with little or no variation in the dynamic response (speed and waveform) of the reported electrostatic voltage being measured. Disclosed is a feedback circuit that provides the spacing independence of the speed of response of an electrostatic voltmeter. In particular, the method and apparatus of the invention provides an AC-type auxiliary feedback loop that provides a means for a DC-feedback electrostatic voltmeter to maintain a fixed gain and thus stable response of the DC loop over a broad range of distances between the sensing electrode and measured surface.

### BACKGROUND OF THE INVENTION

This invention relates to the electrical measurement art, and more particularly to a new and improved method and apparatus for detection and measurement of electrostatic quantities such as electrostatic fields, voltages and charges.

The invention described herein is related to contactless measurement of electrostatic voltages and/or electric fields. The basic principle of operation of these kinds of instruments is known since 1898 when it was proposed by Lord Kelvin, hence the name of the technique, the Kelvin probe. Lord Kelvin, “Contact Electricity of Metals”, Philos. Mag., 46:82-120, 1898. It is also known as a capacitive probe method. FIG. 1 illustrates the basics of the Kelvin method. It shows a parallel plate capacitor 10 comprising a pair of plates 12, 14 with a capacitance C, and a potential difference V_{C} between the plates 12, 14 while ammeter I indicates any current flow between the plates of the capacitor. The charge Q_{C} accumulated on the plates is:

Q_{C}=CV_{C} (1)

From this definition, the current

$${I}_{T} = \frac{d Qc}{d t}$$

that flows between the plates 12, 14 can be produced by two factors: change of the voltage or change of the capacitance (or both).

$${I}_{T} = \frac{d Qc}{d t} = {I}_{1} + {I}_{2} \\ where C \frac{d Vc}{d t} is {I}_{1 ,} {V}_{C} \frac{d c}{d t} = {I}_{2} and {I}_{T} = total current . \qquad ( 2 )$$

In the Kelvin probe the sensing electrode is one of the plates of the capacitor 10 while the other plate is the surface of the measured object. If the voltage V_{C} between the plates is not zero and the sensing electrode is put into motion, changes of the capacitance number

$$\frac{d c}{d t}$$

result in a flow of the current I₂ through the sensor. When the voltage V_{C} is constant, this current I₂ depends on the perpendicular movement of the sensor relative to the surface only, i.e.:

$${I}_{2} = {V}_{C} \frac{d C}{d t} \qquad ( 3 )$$

While for constant position of the plates (no perpendicular motion), the current I₁ depends on a change of the voltage

$$( \frac{d Vc}{d t} )$$

only, i.e.:

$${I}_{1} = C \frac{d Vc}{d t} \qquad ( 4 )$$

When both the capacitance (C) and the voltage (V_{C}) change with time, the total current I_{T} is equal to the sum of the two current components, i.e.:

$${I}_{T} = C \frac{d Vc}{d t} + {V}_{C} \frac{d c}{d t} = {I}_{1} + {I}_{2} \qquad ( 5 )$$

A broad variety of improvements and modifications has been introduced to the basic method concept since Lord Kelvin's time. The two most popular applications originating from Kelvin's invention are an electrostatic voltmeter and an electrostatic fieldmeter. The scope of the invention described herein pertains to, but is not limited to, construction and operation of an electrostatic voltmeter (ESVM). Examples of electrostatic voltmeters may be found, for example, in U.S. Pat. No. 4,205,267 issued May 1980, U.S. Pat. No. 3,525,936 issued 1970, U.S. Pat. No. 3,611,127 issued 1971, U.S. Pat. No. 3,712,967 issued 1973, U.S. Pat. No. 4,106,869 issued 1978 and U.S. Pat. No. 4,797,620 issued Jan. 10, 1989 and in R. E. Vosteen and R. Bartuileas, Engineering Dielectrics, Volume IIB, chapter entitled “Electrostatic Charge Measurements”, pages 440-489, ASTM 2nd Edition, 1987. A non-contacting ESVM usually features a sinusoidally vibrating sensor, capacitively coupled with a measured object. The current I₂ induced in the sensor due to the presence of a voltage E associated with the measured surface relative to the reference potential (V_{S}) of the sensor electrode is:

$${I}_{2} = {V}_{C} \frac{d C}{d t} \qquad ( 6 )$$

where V_{C} is the difference of potential between the test surface and the vibrating sensor, (i.e.: V_{C}=E−V_{S}) and dc/dt is the time rate of change of the capacitance between measured surface and sensor electrode.

An example of a prior art electrostatic voltmeter circuit is shown in FIG. 2. In this DC voltage-following measuring device (i.e. ESVM) the output of an integrator amplifier 20 drives a DC feedback loop 22 to produce a sensor reference voltage (V_{S}) to replicate the voltage (E) on the measured surface 24. The feedback voltage is applied to the sensor 26 (sometimes also referred to hereinafter as “sensing electrode” or “sensor electrode”) via its connection to the non-inverting input 28 of a summing amplifier 30 and, if the feedback voltage (V_{S}) is made equal to the measured surface voltage E, the voltage V_{C} between the measured surface 24 and the sensing electrode 26 will be nullified to zero. When the voltage V_{C} between the sensor 26 and the measured surface 24 equals zero, the current I₂ equals zero.

The ESVM of FIG. 2 represents a closed loop feedback control system where the potential V_{S} of the sensing electrode 26 “follows” the potential on the measured surface 24 by producing a DC feedback potential to produce V_{S} equal to E. Additionally, the voltage from the integrator amplifier 20 may also be delivered to the sensor's housing (enclosure) 34, shielding the sensor from the influence of stray electric fields. All the ESVMs utilizing the above described DC feedback technique rely on the ability of the DC control loop system to follow the electric potential on the measured surface 24. When a change in the electric potential of the measured surface 24 occurs, this will result in the change of the voltage V_{C} thus generating the factor

$${V}_{C} \frac{d c}{d t}$$

of equation (3) hereinabove to produce a current I₂ into the sensor 26. The magnitude of the current I₂ for a given V_{C} is dependent upon the

$$\frac{d c}{d t}$$

term and thus is proportional to

$$\frac{1}{D} ,$$

where D is the distance between the measured surface 24 and sensor electrode 26, as conventionally known. As I₂ generates the input signal to the feedback control loop 22, the dynamic response of the loop will be dependent upon the magnitude of I₂ per unit of V_{C} (the potential difference between measured surface and sensor).

Shown in FIG. 3 is a graph of the relative amplitude of the AC voltage obtained at the output of amplifier 42 of the ESVM of FIG. 2 under the conditions of, 1) the DC feedback loop is returned to ground reference rather than to the output of amplifier 20, and 2) voltage E is 10 volts DC. The graph data is taken at a fixed gain control setting while the sensor to measured surface spacing (D) is varied over a 0.5 mm to 4 mm spacing distance. As shown under this open loop condition, over the spacing range (0.5 to 4 mm) the AC amplitude varies over an 8 to 1 range as conventionally anticipated. This shows the

$$\frac{1}{D}$$

response characteristics of the prior art ESVM. This gain change produces the undesirable ESVM closed loop response characteristic shown in FIG. 4.

Prior art DC feedback loop circuits are adjusted for optimized response to the

$${V}_{C} \frac{d c}{d t}$$

factor of the current I₂ for variable value of the

$$\frac{d c}{d t}$$

term as a function of the distance between the sensor and the surface of the measured object by use of a “gain adjust” control 46 shown at amplifier 42 in FIG. 2. This allows the gain and thus the dynamics of the DC loop to be tuned after any change of the measurement distance between the sensing electrode and the measured object occurs. The graph of FIG. 4 presents an example of the output obtained at V_{Sout} 50 of the DC feedback ESVM of FIG. 2 at a fixed gain control setting to a step potential represented by curve 52 in FIG. 4 applied to the measured surface. Curve 54 represents the response when the sensor-to-surface spacing is 0.5 mm and curve 56 represents the response when the sensor-to-surface spacing is 4 mm. When the sensor-to-surface distance is increased, the

$$\frac{d c}{d t}$$

term becomes smaller, hence

$${V}_{C} \frac{d c}{d t}$$

is smaller to produce a smaller value of I₂ and therefore the response of the voltmeter is slowed down (undershoot). This is illustrated by curve 56. Similarly, when the sensor is brought closer to the measured surface, the

$$\frac{d c}{d t}$$

term increases and the ESVM will have a tendency to overshoot and become oscillatory. This is illustrated by curve 54. Compensation is made to the over/undershoot response by adjusting the “gain adjust” control 46 at amplifier 42 to produce a flat response characteristic. This is illustrated by curve 58 which represents the response when the sensor-to-surface spacing is 2.0 mm. This behavior is perceived as a major inconvenience by users of the DC feedback ESVMs particularly where the distance can not be held fixed during a measurement sequence such as when monitoring moving surfaces. The design proposed by the invention described herein overcomes the ESVM inability to maintain the optimized response to changes in the electric potential of the surfaces under test with varying distances without the necessity to adjust a variable gain control.

### SUMMARY OF THE INVENTION

It is an object of this invention to provide an electrostatic voltmeter apparatus and method to measure electrostatic voltages and fields associated with surfaces which apparatus and method drive the electrode sensor to the same potential as the measured unknown and in a manner providing a dynamic response characteristic which is independent of the sensor electrode to test surface spacing. The invention features a novel feedback circuit that provides the spacing independence of the speed of response of an electrostatic voltmeter. The method and apparatus of the invention provides an AC-type auxiliary feedback loop that provides a means for a DC-feedback electrostatic voltmeter to maintain a fixed gain and thus stable response of the DC loop over a broad range of distances between the sensing electrode and a measured surface.

The foregoing and additional advantages and characterizing features of the invention will become clearly apparent upon a reading of the ensuing detailed description together with the included drawings.

### BRIEF DESCRIPTION OF THE DRAWING

The invention is illustrated in the drawings in which like reference characters designate the same or similar parts throughout the figures of which:

FIG. 1 is a diagrammatic view of a prior art Kelvin probe;

FIG. 2 is a schematic diagram of a prior art electrostatic voltmeter;

FIG. 3 is a graph of the magnitude of AC voltage as a function of sensor to measured surface spacing, which voltage is obtained at the output of an intermediate amplifier 42 in the circuit of FIG. 2;

FIG. 4 is a graph of the output response of the circuit of FIG. 2 to a step input of measured voltage at various sensor-to-surface spacing at a fixed gain control setting;

FIG. 5 is a schematic diagram of an electrostatic voltmeter according to this invention;

FIG. 6 is a graph of AC voltage as a function of sensor to measured surface spacing which voltage is obtained at the output of an intermediate amplifier in the circuit of FIG. 5; and

FIG. 7 is a graph of the output response of the circuit of FIG. 5 to a step input of measured voltage at various sensor-to-surface spacing.

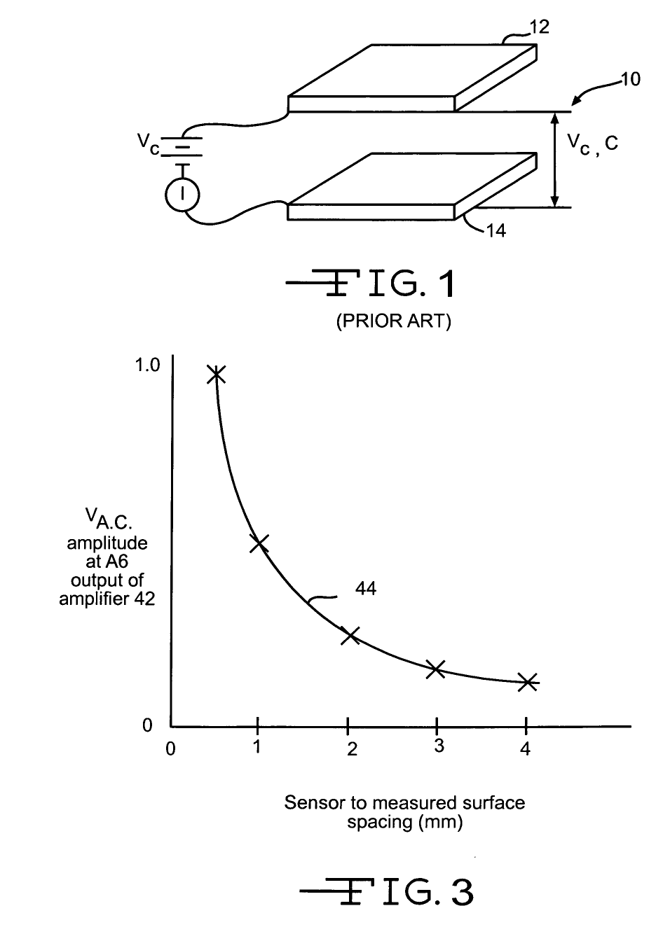

### DETAILED DESCRIPTION OF THE INVENTION

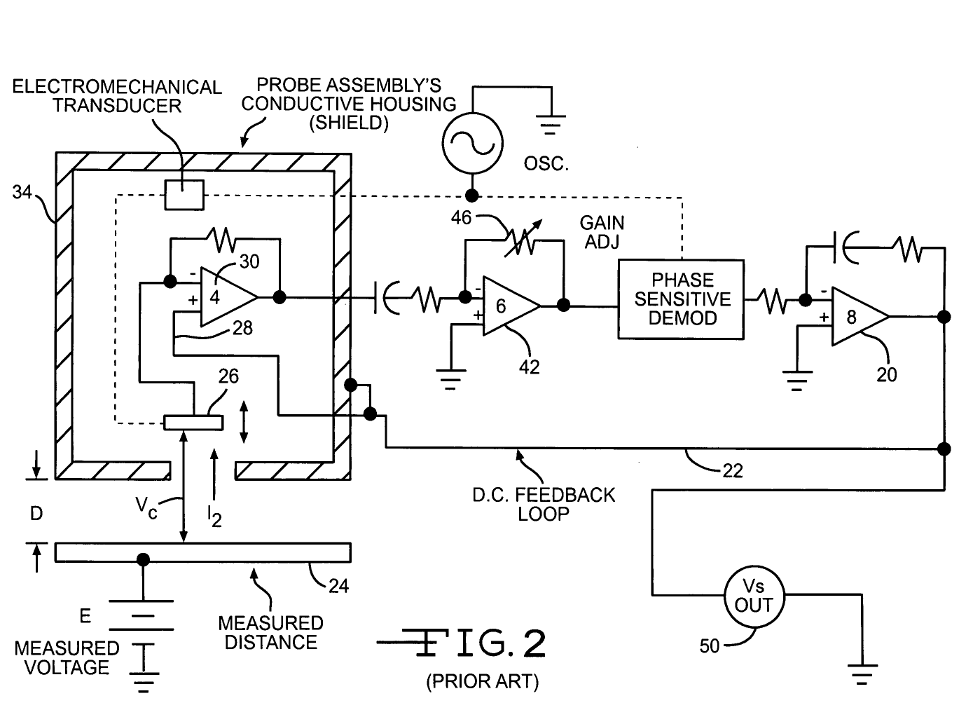

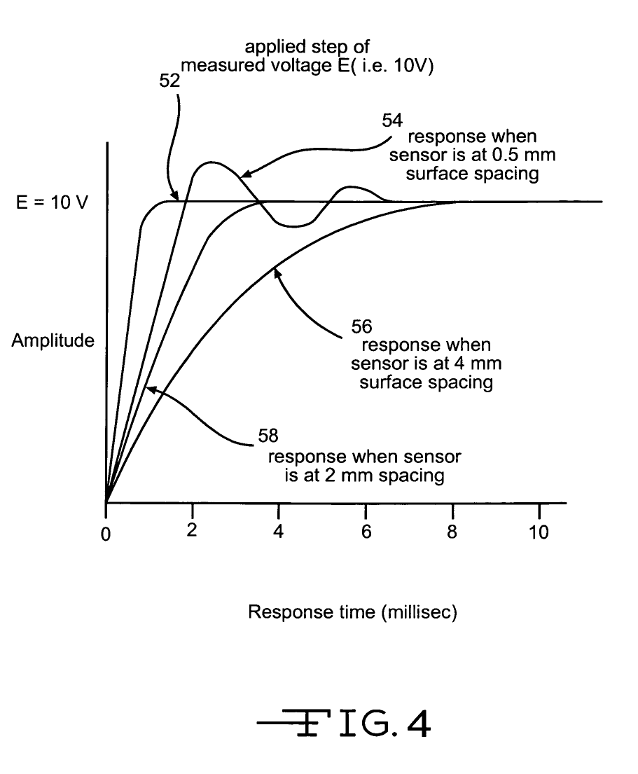

The invention presented herein introduces a novel feedback circuit that provides spacing independence of the speed of response of an electrostatic voltmeter. This novel technique provides an AC-type auxiliary feedback loop that provides a means for a DC-feedback ESVM to maintain a fixed gain and thus stable response of the DC loop over a broad range of distances between the sensing electrode and a measured surface. As introduced by U.S. Pat. No. 4,797,620 issued Jan. 10, 1989 entitled “High Voltage Electrostatic Surface Potential Monitoring System Using Low Voltage A.C. Feedback”, a technique was developed to allow a low amplitude AC signal to be used as a feedback signal to the vibrating capacitor sensor as a reference rather than the usual DC voltage as used in prior art devices (as typified by the device of FIG. 2). The disclosure of U.S. Pat. No. 4,797,620 is incorporated herein by reference. This technique of U.S. Pat. No. 4,797,620 produced a low voltage AC output signal which is representative of the DC voltage level applied to the measured surface, while the amplitude of this representative AC signal amplitude was stable as a function of the vibrating sensor to measure surface distances. As discussed in U.S. Pat. No. 4,797,620 (i.e. the '620 patent), a summation of currents I₁, due to

$$C \frac{d V}{d t}$$

and I₂, due to

$${V}_{C} \frac{d c}{d t}$$

(

$$\frac{d c}{d t}$$

being a function of the rate change of the AC signal applied as a reference to the sensor), both distance dependent terms, produced a ratio

$$C \frac{d V}{d t} / {V}_{C} \frac{d c}{d t}$$

which was independent of spacing. As shown in the '620 patent, due to the

$$\frac{d V c}{d t} and \frac{d c}{d t}$$

terms operating on the same vibrating electrode sensor, the relation between the AC output and measured DC input was reduced to

$$\frac{Δ C}{C} = \frac{Δ V}{V} ( at small ratios of \frac{Δ C}{C} )$$

thus allowing precision measurement of E (the measured surface voltage) by measuring ΔV, the amplitude of the AC signal feedback to the vibrating sensor.

The advantage of the device of the '620 patent lies with the ability to perform non-contacting, distance independent measurements of high voltage using relatively small amplitude AC feedback signals. The disadvantage of the device of the '620 patent arises in its use in applications where a large DC voltage difference between the probe sensor and measured surface could exist, because no DC feedback is provided to the sensor to drive it to the voltage level of the measured surface to eliminate the possibility of electrical arc-over there-between. For these close spacing applications, it becomes necessary to drive the probe sensor to the same potential as the measured surface to avoid arc-over.

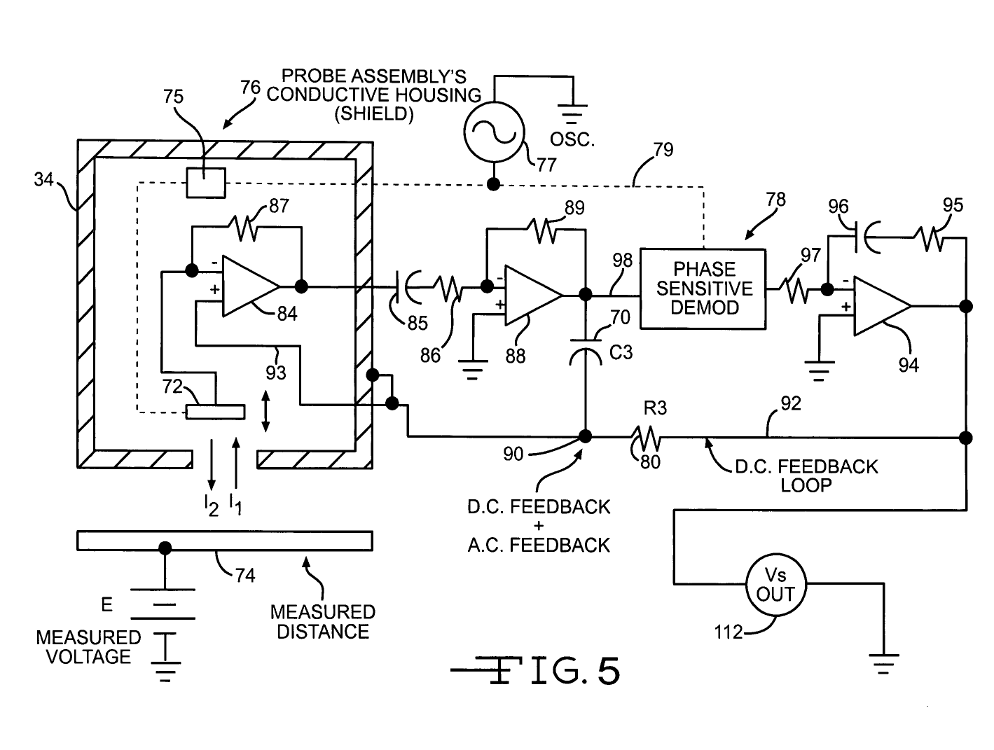

It is therefore an object of this invention to provide an electrostatic voltmeter to measure electrostatic voltages and fields associated with surfaces which employs DC feedback to drive the electrode sensor to the same potential as the measured unknown and which has a dynamic response characteristic which is independent of the sensor electrode to test surface spacing. Shown in FIG. 5 is a schematic representation of a device which accomplishes the purpose of the invention. An AC signal is applied as a reference to the sensor electrode through capacitor C3, also designated 70, to produce a current I₁, due to C

$$\frac{d {V}_{AC}}{d t}$$

where C is the capacitance between the sensor electrode 72 and measured surface 74 and V_{AC} is the applied AC voltage between sensor electrode 72 and the measured or test surface 74. Sensor electrode 72 is vibrated by an electromechanical transducer 75, shown here within housing 76, which is operated by an oscillator 77 in a known manner. A phase sensitive demodulator 78 receives the output of oscillator 77 as a reference via line 79.

Current I₁ is made to be equal and opposite to I₂, the current due to

$${V}_{C} \frac{d c}{d t}$$

where V_{C} is the DC voltage difference between the sensor's reference DC voltage, as applied through R3, also designated 80, and the measured surface voltage E, and

$$\frac{d c}{d t} ,$$

the change in capacitance between sensor 72 and surface 74, I₂ being the usual current produced by the prior art ESVM devices as shown in FIG. 2. To produce the equal and opposite current I₁, the output of amplifier 84, is coupled through capacitor 85 and resistor 86 to amplifier 88, the gain of which can be several hundred at the sensor's capacitive modulation frequency (i.e.: 500 Hz to several KHz or more). In any event, the gain of amplifier 88, once selected, remains fixed in contrast to the adjustable gain amplifier 42 in the prior art ESVM of FIG. 2. Amplifiers 84 and 88 both are connected as summing amplifiers by virtue of resistors 87 and 89 being connected from the outputs to the inverting inputs of the amplifiers 84 and 88, respectively. The amplified AC signal at the output of amplifier 88 is summed at 90 with the normal DC feedback 92 and applied via line 93 to the positive terminal of amplifier 84 as a reference signal to the sensor electrode 72. This AC signal at the sensor will produce an I₁ current signal equal to the

$$C \frac{d {V}_{AC}}{d t}$$

term to sum with the

$${V}_{C} \frac{d c}{d t}$$

current term to produce zero or close to zero net current. Any non-zero net current will appear as a finite current into the summing node of amplifier 84 to be amplified to produce the AC signal at the output of amplifier 84 which is multiplied by the gain of amplifier 88 and applied to the sensor.

In this way a closed loop system is formed to produce the required voltage at the output of amplifier 88 to nullify the current into the summing node of amplifier 84. If the gain of the negative feedback loop is high, the net current at the summing node will be very low, thus producing good nullification of the I₂ current signal with the AC voltage induced I₁ signal. The nullification of current I₂ by current I₁ is independent of sensor to test surface spacing because at, for example, increased spacing the value of =2 decreases at a ratio of

$$\frac{1}{D}$$

### (D=spacing) for any fixed DC voltage across the capacitor C (the sensor to measured surface capacitance) while the value of I₂ also decreases at the rate of

$$\frac{1}{D}$$

with a fixed AC voltage level from amplifier 88. Thus the ratio of the measured surface DC voltage value to the AC signal amplitude remains fixed over a large sensor to measured surface spacing.

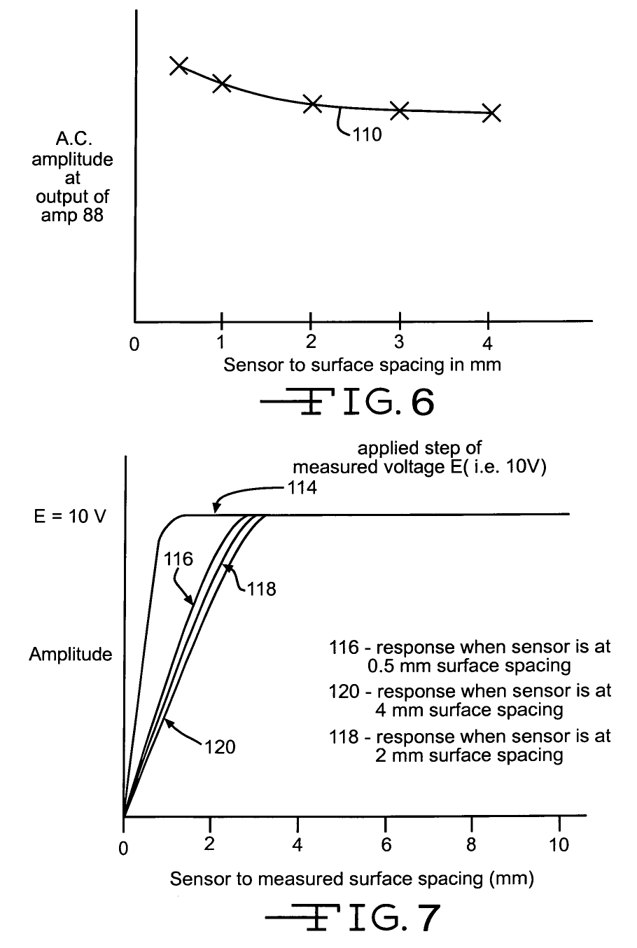

Shown in FIG. 6 is a graph of the relative amplitude of the AC voltage obtained at the output of amplifier 88 of the ESVM of FIG. 5, the ESVM of this invention. Here again the data is taken under the conditions of 1) the DC feedback is disconnected at the output of amplifier 94, while line 92 is returned to ground and, 2) measured or test surface voltage E is 10 volts DC. Amplifier 94 is connected as an integrating amplifier by virtue of the series combination of resistor 95 and capacitor 96 connected from the output to the inverting input. The output of phase sensitive demodulator 78 is applied through resistor 97 to the inverting input of amplifier 94. The output at amplifier 88 is applied via line 98 to the input of demodulator 78. The graph data is taken as the spacing distance between sensor element 72 and measured surface 74 is varied over a range of 0.5 mm to 4.0 mm. As shown by the curve 110 in FIG. 6, the AC amplitude of the AC signal is relatively fixed over a spacing change of 0.5 mm to 4 mm.

The D.C. feedback loop is re-established by reconnection of line 92 from ground to the output of amplifier 94 to measure the response of the overall D.C. loop due to the use of A.C. feedback signal connected at 90. The response of the output to measured surface voltage is illustrated by the graph of FIG. 7 which shows that, over a measured surface to sensor spacing of 0.5 mm to 4.0 mm, the dynamic response characteristic remains essentially fixed with no overshoot or undershoot components. In particular, the graph of FIG. 7 illustrates the output obtained at V_{Sout} 112 of the circuit of FIG. 5 to a step potential represented by curve 114 in FIG. 7 applied to the measured surface 74. Curves 116, 118 and 120 represent the response when the sensor-to-surface spacing is 0.5 mm, 2.0 mm and 4.0 mm, respectively. Thus, the dynamic response has no overshoot or undershoot.

Thus the object of the invention has been accomplished using the technique and apparatus of this invention. Variations in the embodiment of this invention can be produced to accomplish additional features of the ESVM without departing from the scope of the invention such as, for example, high voltage range operation by using high voltage amplifier techniques for amplifier 94, use of a single FET device in the probe to replace amplifier 84 to reduce the size and number of connections to the probe, etc.

While an embodiment of the invention has been described in detail, that has been done for the purpose of illustration, not limitation.

What is claimed is:

1. A non-contacting electrostatic detector comprising:
(a) a detector electrode sensitive to electrostatic quantities such as electrostatic fields, voltages, charges and the like;
(b) means operatively associated with the detector electrode for varying capacitive coupling between the electrode and a surface bearing an electrostatic quantity to which the electrode is exposed;
(c) a circuit operatively connected to the electrode for developing an electrical signal indicative of a property of the electrostatic quantity to which the detector electrode is exposed;
(d) the circuit having a first portion for providing a DC feedback signal and applying that signal to the detector electrode to drive the electrode to the same potential as the surface bearing the electrostatic quantity; and
(e) the circuit having a second portion for providing an AC feedback signal and applying that signal to the detector electrode which enables the first portion of the circuit to maintain a fixed gain and thus stable response of the first portion of the circuit over a range of distances between the detector electrode and the surface bearing the electrostatic quantity sufficient such that the electrostatic detector has a dynamic response characteristic independent of the spacing between the detector and the surface bearing the electrostatic quantity.

2. The detector according to claim 1, wherein a first current flows between the surface bearing the electrostatic quantity and the detector electrode as a result of varying the capacitive coupling between the electrode and the surface and wherein a second current equal and opposite to the first current flows between the electrode and the surface as a result of the DC feedback signal and the AC feedback signal being applied to the detector electrode.

3. The detector according to claim 2, wherein the first current is due to the DC voltage difference between a reference DC voltage applied to the detector electrode and the measured voltage on the surface bearing the electrostatic quantity and to the change in capacitance between the detector electrode and the surface bearing the electrostatic quantity and wherein the second current is due to the capacitance between the detector electrode and the surface bearing the electrostatic quantity and to the change in the AC feedback signal applied to the detector electrode.

4. The detector according to claim 2, wherein in response to an increase in spacing D between the detector electrode and the surface bearing the electrostatic quantity the magnitude of the first current decreases at a ratio of 1/D for a fixed DC voltage across the capacitance between the detector electrode and the surface and the magnitude of the second current also decreases at a ratio of 1/D for a fixed voltage level of the AC feedback signal.

5. The detector according to claim 1, wherein the circuit comprises a summing amplifier having an input and having an output operatively coupled to means for providing the electrical signal indicative of the property of the electrostatic quantity to which the detector electrode is exposed and wherein the first portion of the circuit comprises a DC feedback loop operatively connected to the detector electrode through the summing amplifier.

6. The detector according to claim 5, wherein the circuit comprises a fixed gain amplifier having an input coupled to the output of the summing amplifier and having an output and wherein the DC feedback loop comprises a phase sensitive demodulator having an input connected to the output of the fixed gain amplifier, an integrator amplifier having an input coupled to the output of the phase sensitive demodulator and having an output, and means coupling the output of the integrator amplifier to the detector electrode through the summing amplifier.

7. The detector according to claim 6, wherein the capacitive coupling between the electrode and the surface is varied at a modulation frequency and wherein the gain of the fixed gain amplifier has a relationship to the modulation frequency.

8. The detector according to claim 1, wherein the circuit comprises a summing amplifier having an input and having an output operatively coupled to means for providing the electrical signal indicative of the property of the electrostatic quantity to which the detector electrode is exposed and wherein the second portion of the circuit comprises an AC feedback loop operatively connected to the detector electrode through the summing amplifier.

9. The detector according to claim 8, wherein the circuit comprises a fixed gain amplifier having an input coupled to the output of the summing amplifier and wherein the AC feedback loop comprises a capacitor connected to the output of the fixed gain amplifier and means coupling the capacitor to the detector electrode through the summing amplifier.

10. The detector according to claim 9, wherein the capacitive coupling between the electrode and the surface is varied at a modulation frequency and wherein the gain of the fixed gain amplifier has a relationship to the modulation frequency.

11. A method for detecting electrostatic quantities such as electrostatic fields, voltages, charges and the like comprising:
(a) modulating capacitance between a detector electrode and a surface bearing an electrostatic quantity such as field, voltage, charge and the like;
(b) developing a detector electrical signal from the detector electrode as a result of modulating the capacitance;
(c) providing a DC feedback signal from the detector electrical signal and applying that feedback signal to the detector electrode to drive the detector electrode to the same potential as the surface bearing the electrostatic quantity; and
(d) providing an AC feedback signal from the detector electrical signal and applying the AC feedback signal to the detector electrode as a reference;
(e) so that a dynamic response characteristic results which is independent of spacing between the detector electrode and surface bearing the electrostatic quantity.

12. The method according to claim 11, wherein a first current flows between the surface bearing the electrostatic quantity and the detector electrode as a result of varying the capacitive coupling between the electrode and the surface and wherein a second current equal and opposite to the first current flows between the electrode and the surface as a result of the DC feedback signal and the AC feedback signal being applied to the detector electrode.

13. The method according to claim 12, wherein the first current is due to the DC voltage difference between a reference DC voltage applied to the detector electrode and the measured voltage on the surface bearing the electrostatic quantity and to the change in capacitance between the detector electrode and the surface bearing the electrostatic quantity and wherein the second current is due to the capacitance between the detector electrode and the surface bearing the electrostatic quantity and to the change in the AC feedback signal applied to the detector electrode.

14. The method according to claim 12, wherein in response to an increase in spacing between the detector electrode and the surface bearing the electrostatic quantity the magnitude of the first current decreases at a ratio of 1/D for a fixed DC voltage across the capacitance between the detector electrode and the surface and the magnitude of the first current also decreases at a ratio of 1/D for a fixed voltage level of the AC feedback signal where D is the spacing between the detector electrode and surface bearing the electrostatic quantity.

15. A non-contacting electrostatic detector comprising:
(a) a detector electrode sensitive to electrostatic quantities such as electrostatic fields, voltages, charges and the like;
(b) means operatively associated with the detector electrode for varying capacitive coupling between the electrode and a surface bearing an electrostatic quantity to which the electrode is exposed;
(c) a summing amplifier connected to the detector electrode and having an output;
(d) a fixed gain amplifier having an input coupled to the output of the summing amplifier and an output;
(e) a DC feedback loop operatively connected to the output of the fixed gain amplifier and to the detector electrode through the summing amplifier to drive the detector electrode to the same potential as the surface bearing the electrostatic quantity; and
(f) an AC feedback loop connected to the output of the fixed gain amplifier and operatively connected to the detector electrode through the summing amplifier;
(g) the AC feedback loop enabling the non-contacting electrostatic detector to maintain a fixed gain and thus stable response of the DC feedback loop over a range of distances between the detector electrode and the surface bearing the electrostatic quantity to provide a dynamic response characteristic independent of the spacing between the detector and the surface bearing the electrostatic quantity.

16. The detector according to claim 15, wherein a first current flows between the surface bearing the electrostatic quantity and the detector electrode as a result of varying the capacitive coupling between the electrode and the surface and wherein a second current equal and opposite to the first current flows between the electrode and the surface as a result of a signal from the DC feedback loop and a signal from the AC feedback loop being applied to the detector electrode.

17. The detector according to claim 16, wherein the first current is due to the DC voltage difference between a reference DC voltage applied to the detector electrode and the measured voltage on the surface bearing the electrostatic quantity and to the change in capacitance between the detector electrode and the surface bearing the electrostatic quantity and wherein the second current is due to the capacitance between the detector electrode and the surface bearing the electrostatic quantity and to the change in the signal from the AC feedback loop applied to the detector electrode.

18. The detector according to claim 16, wherein in response to an increase in spacing between the detector electrode and the surface bearing the electrostatic quantity the magnitude of the first current decreases at a ratio of 1/D for a fixed DC voltage across the capacitance between the detector electrode and the surface and the magnitude of the second current also decreases at a ratio of 1/D for a fixed voltage level of the signal from the AC feedback loop.

19. The detector according to claim 15, wherein the capacitive coupling between the electrode and the surface is varied at a modulation frequency and wherein the gain of the fixed gain amplifier has a relationship to the modulation frequency.

20. The detector according to claim 15, wherein the DC feedback loop comprises a phase sensitive demodulator having an input connected to the output of the fixed gain amplifier, an integrator amplifier having an input connected to the output of the phase sensitive demodulator and having an output, and means coupling the output of the integrator amplifier to the detector electrode through the summing amplifier.

21. The detector according to claim 15, wherein the AC feedback loop comprises a capacitor connected to the output of the fixed gain amplifier and means coupling the capacitor to the detector electrode through the summing amplifier.
